(19) United States
(12) Patent Application Publication
(10) Pub. No.: US 2025/0231243 A1
(43) Pub. Date: Jul. 17, 2025

(54) FUZZY-LOGIC-BASED APPARATUS, SYSTEM, AND METHOD FOR CALCULATING STATE SAFETY OF ENERGY STORAGE SYSTEM

(71) Applicant: KOREA ELECTRONICS TECHNOLOGY INSTITUTE, Seongnam-si (KR)

(72) Inventors: Hyo Sub CHOI, Yongin-si (KR); Chang Woo KIM, Siheung-si (KR); Tae Il YUN, Seongnam-si (KR)

(21) Appl. No.: 19/095,608

(22) Filed: Mar. 31, 2025

Related U.S. Application Data
(63) Continuation of application No. PCT/KR2023/004637, filed on Apr. 6, 2023.

(30) Foreign Application Priority Data
Dec. 9, 2022 (KR) 10-2022-0171415

(51) Int. Cl. G01R 31/367; G01R 31/374; G01R 31/3835; G01R 31/392; G01R 31/396; G05B 13/02; H01M 10/42

(52) U.S. Cl. CPC G01R 31/367; G01R 31/374; G01R 31/3835; G01R 31/392; G01R 31/396; G05B 13/0275; H01M 10/4285

(57) ABSTRACT

Proposed is a fuzzy-logic-based method for calculating the state safety of an energy storage system. The method may be performed by a state safety calculation apparatus. The method may also include defining a voltage safety membership function and a temperature safety membership function, and collecting information about charging state, voltage, and temperature from the energy storage system. The method may further include calculating integrated levels of safety by applying a fuzzy rule to the voltage safety membership function and the temperature safety membership function with respect to the collected information. The method may further include calculating the total integrated level of safety by summing the calculated integrated levels of safety; and calculating the momentary integrated level of safety through defuzzification of the total integrated level of safety.

### CROSS REFERENCE TO RELATED APPLICATIONS

This is a continuation application of International Patent Application No. PCT/KR2023/004637 filed on Apr. 6, 2023, which claims priority to Korean patent application No. 10-2022-0171415 filed on Dec. 9, 2022, contents of each of which are incorporated herein by reference in their entirety.

### BACKGROUND

### Technical Field

The present disclosure relates to a technology for managing the state safety of an energy storage system (ESS), and more specifically, to a fuzzy logic based apparatus, system, and method for calculating a state safety of the energy storage system, which calculate an indicator of safety related to fire, explosion, etc. of the energy storage system based on information collected from the energy storage system.

### Description of Related Technology

In the renewable energy field, energy big data analysis and inference operations are being utilized. In the secondary battery material industry, research on battery fire prevention and safety is actively underway in relation to recent battery fires and explosions in energy storage systems/electric vehicles.

### SUMMARY

One aspect is a fuzzy logic based apparatus, system, and method for calculating a state safety of an energy storage system, which calculate an integrated safety for the status of the energy storage system based on fuzzy logic for information on charge state, voltage, and temperature collected from the energy storage system.

Another aspect is a fuzzy logic based method for calculating a state safety of an energy storage system, the method including: by a state safety calculation apparatus, defining a voltage safety membership function and a temperature safety membership function; by the state safety calculation apparatus, collecting information on charge state, voltage, and temperature from the energy storage system; by the state safety calculation apparatus, calculating an integrated safety by applying a fuzzy rule to the voltage safety membership function and the temperature safety membership function for the collected information; by the state safety calculation apparatus, calculating a total integrated safety by summing up the calculated integrated safety; and by the state safety calculation apparatus, calculating an instantaneous integrated safety through defuzzification of the total integrated safety.

The method according the present disclosure may further include: after calculating the instantaneous integrated safety, by the state safety calculation apparatus, calculating the integrated safety for a specific period by calculating an average of the instantaneous integrated safety for each period.

When defining, the state safety calculation apparatus may define the voltage safety membership function and the temperature safety membership function to infer the integrated safety using Mamdani method.

The fuzzy rule may represent the voltage safety and the temperature safety as in Table below.

TABLE

| | temperature safety | | | | |
|---|---|---|---|---|---|
| | Catastrophic | Critical | Neutral | Marginal | Negligible |
| | (E) | (D) | (C) | (B) | (A) |
| voltage safety | (Very dangerous) | (Dangerous) | (Normal) | (Safe) | (Very safe) |
| Catastrophic | E | E | E | D | C |
| (E) | | | | | |
| (Very dangerous) | | | | | |
| Critical | E | D | D | C | B |
| (D) | | | | | |
| (Dangerous) | | | | | |
| Neutral | E | D | C | C | B |
| (C) | | | | | |
| (Normal) | | | | | |
| Marginal | D | C | C | B | B |
| (B) | | | | | |
| (Safe) | | | | | |
| Negligible | C | B | B | B | A |
| (A) | | | | | |
| (Very safe) | | | | | |

When calculating the integrated safety, the state safety calculation apparatus may calculate the integrated safety using Equation 1 below.

$$μ X∩Y ( x ) = p r od [ μ X ( x ) , μ Y ( x ) ] = μ X ( x ) \times μ Y ( x ) = Z ( x ) \qquad EQUATION 1$$

Z: Integrated safety
X: Voltage safety membership function
x: Voltage
Y: Temperature safety membership function
y: Temperature
μ: Weight

When calculating the instantaneous integrated safety, the state safety calculation apparatus may calculate the instantaneous integrated safety (c) through defuzzification by using a center of gravity method according to Equation 2 below.

$$c = \frac{{{\sum }_{x = a}}^{b} μ A ( x ) x}{{{\sum }_{x = a}}^{b} μ A ( x )} \qquad EQUATION 2$$

c: Instantaneous integrated safety
A: Membership function
x: Calculated integrated safety
μ: Weight

Another aspect is a fuzzy logic based apparatus for calculating a state safety of an energy storage system, the apparatus comprising: a communicator performing communication with the energy storage system; and a controller defining a voltage safety membership function and a temperature safety membership function, collecting information on charge state, voltage, and temperature from the energy storage system through the communicator, calculating an integrated safety by applying a fuzzy rule to the voltage safety membership function and the temperature safety membership function for the collected information, calculating a total integrated safety by summing up the calculated integrated safety, and calculating an instantaneous integrated safety through defuzzification of the total integrated safety.

Another aspect is a fuzzy logic based system for calculating a state safety of an energy storage system, the system comprising: the energy storage system; and a state safety calculation apparatus defining a voltage safety membership function and a temperature safety membership function, collecting information on charge state, voltage, and temperature from the energy storage system, calculating an integrated safety by applying a fuzzy rule to the voltage safety membership function and the temperature safety membership function for the collected information, calculating a total integrated safety by summing up the calculated integrated safety, and calculating an instantaneous integrated safety through defuzzification of the total integrated safety.

According to the present disclosure, it is possible to calculate the integrated safety for the state of the energy storage system based on fuzzy logic for the information on the state of charge, voltage, and temperature collected from the energy storage system.

The state safety calculation apparatus according to the present disclosure calculates the integrated safety for the state of the energy storage system by reflecting information on the state of charge and temperature in addition to voltage, so it can provide a more accurate indicator of safety related to fire, explosion, etc. of the energy storage system. That is, the state safety calculation apparatus can calculate the integrated safety as a reliable safety indicator by performing fuzzy logic based numerical and weight calculations for the information on the state of charge, voltage, and temperature of the energy storage system. The calculated integrated safety provides a more precise safety indicator than a safety indicator based only on voltage or temperature, and enables accurate analysis by quantifying the values of a certain range of information for all cells constituting the energy storage system through a membership function definition that considers the state of charge.

The calculation system according to the present disclosure calculates the integrated safety based on information about the state of charge, voltage, and temperature of the energy storage system, so that reliable analysis can be performed in the fire prevention and battery anomaly detection of the energy storage system.

The calculation system according to the present disclosure can provide reliable information to users of the energy storage system by presenting a more comprehensive integrated safety through weight calculation of various indicators based on fuzzy logic.

### BRIEF DESCRIPTION OF THE DRAWINGS

FIG. 1 is a diagram showing a fuzzy logic based system for calculating a state safety of an energy storage system according to an embodiment of the present disclosure.

FIG. 2 is a diagram showing the state safety calculation apparatus in FIG. 1.

FIG. 3 is a flowchart showing a fuzzy logic based method for calculating a state safety of an energy storage system according to an embodiment of the present disclosure.

FIGS. 4 to 13 are diagrams showing a process of calculating an instantaneous integrated safety according to the state safety calculation method in FIG. 3.

FIG. 4 is a graph showing a voltage safety membership function that defines a fuzzy set for the state of charge.

FIG. 5 is a graph showing a voltage safety membership function that defines a fuzzy set for the state of discharge.

FIGS. 6, 7, 8A, 8B, 9A, 9B, 10A, 10B, 11A, and 11B are graphs for setting an integrated safety calculated by applying a fuzzy rule to a membership function for the state of charge, voltage, and temperature.

FIG. 12 is a graph showing a total integrated safety obtained by summing up the calculated integrated safety.

FIG. 13 is a graph showing an instantaneous integrated safety calculated through defuzzification of the total integrated safety.

### DETAILED DESCRIPTION

In order to prevent or take measures against dangerous situations such as fires and explosions in energy storage systems by recognizing them in advance, there is a trend to create various indicators based on sensor data generated within the energy storage systems and utilize them as secondary data.

In a method for determining deterioration of cells or battery modules that constitute an energy storage system, the relative aging of battery cells is determined through a voltage indicator and the frequency of maximum and minimum voltage cell extraction values. In this method, first, since indicators such as temperature and state of charge are not included in addition to the voltage indicator, the indicator cannot be considered accurate. Second, since the relative aging is determined through the frequency of cell extraction values, it can be identified for only some cells. Third, since a measured value is calculated as a specific reference value for each state of charge, deterioration determination is inaccurate for data within a certain range of reference values.

However, safety indicators generated from information on battery status in battery fires and explosions in energy storage systems are very important factors from the perspective of energy storage system analysis.

In the following description, only parts necessary to understand embodiments of the present disclosure will be described, and other parts will not be described to avoid obscuring the subject matter of the present disclosure.

Terms used herein should not be construed as being limited to their usual or dictionary meanings. In view of the fact that the inventor can appropriately define the meanings of terms in order to describe his/her own invention in the best way, the terms should be interpreted as meanings consistent with the technical idea of the present disclosure. In addition, the following description and corresponding drawings merely relate to specific embodiments of the present disclosure and do not represent all the subject matter of the present disclosure. Therefore, it will be understood that there are various equivalents and modifications of the disclosed embodiments at the time of the present application.

Now, an embodiment of the present disclosure will be described in detail with reference to the accompanying drawings.

### State Safety Calculation System

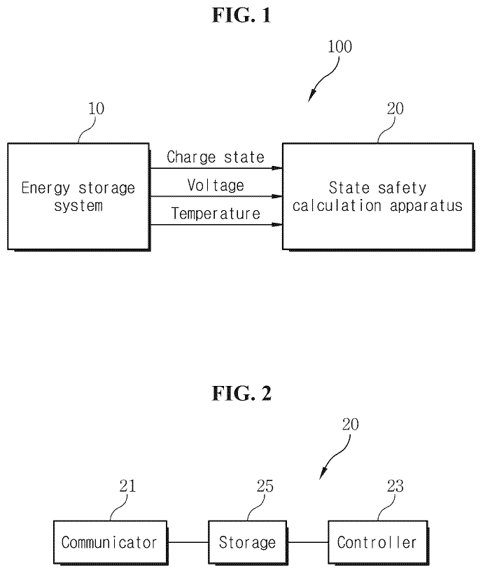

FIG. 1 is a diagram showing a fuzzy logic based system for calculating a state safety of an energy storage system according to an embodiment of the present disclosure.

Referring to FIG. 1, a fuzzy logic based system 100 (hereinafter referred to as the ‘calculation system’) for calculating a state safety of an energy storage system 10 according to this embodiment is a system that calculates the state safety as a safety indicator of the energy storage system 10. The calculation system 100 according to this embodiment calculates, as the state safety, the integrated safety for the state of the energy storage system 10 based on fuzzy logic for information on the state of charge, voltage, and temperature collected from the energy storage system 10.

The calculation system 100 according to this embodiment includes the energy storage system 10 and a state safety calculation apparatus 20 (hereinafter referred to as the ‘calculation apparatus’).

The energy storage system 10 is a system that stores and preserves energy, and plays a role in supplementing the intermittency, which is a weakness of renewable energy. The energy storage system 10 includes a secondary battery that can be recharged and discharged, and a lithium-ion battery is typically used as the secondary battery. In addition, various materials such as lithium iron phosphate, vanadium, hydrogen, and ammonia are being considered as secondary batteries. Based on cells which are secondary batteries, the energy storage system 10 includes a plurality of battery modules in which cells are modularized.

The energy storage system 10 provides information on the state of charge, voltage, and temperature required for calculating the integrated safety to the calculation apparatus 20.

In addition, the calculation apparatus 20 calculates the integrated safety for the state of the energy storage system 10, based on fuzzy logic for the information collected from the energy storage system 10.

Generally, based on the information collected from the energy storage system 10, monitoring is performed on operational and safety indicators such as SoC (State of Charge), SoH (State of Health), SoS (State of Safety), and SoL (State of Life), and dangerous situations such as fire and explosion of the energy storage system 10 are recognized and prevented in advance based on these safety indicators.

The calculation apparatus 20 according to this embodiment calculates the integrated safety as a reliable safety indicator by performing fuzzy logic based numerical and weight calculations on the information collected from the energy storage system 10. In other words, the calculation apparatus 20 calculates the integrated safety as the state safety of the battery for each period by calculating weights based on fuzzy logic according to the battery charge state and data range from the information collected from the energy storage system 10.

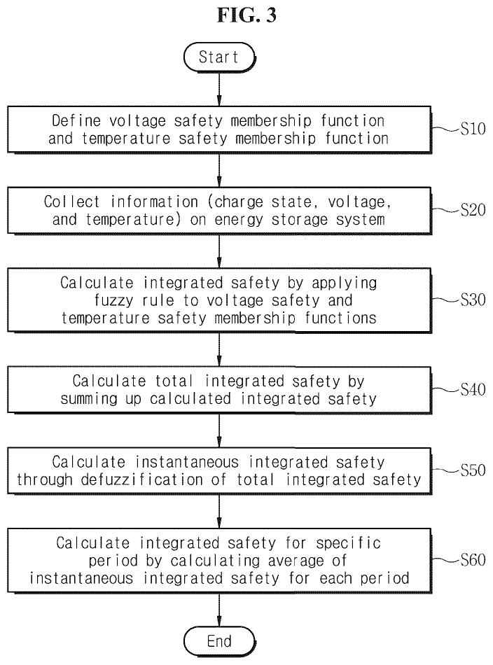

Hereinafter, the calculation apparatus 20 according to the embodiment will be described with reference to FIGS. 1 and 2. Here, FIG. 2 is a diagram showing the state safety calculation apparatus 20 in FIG. 1.

The calculation apparatus 20 according to the embodiment includes a communicator 21, a storage 23, and a controller 25.

The communicator 21 performs communication with the energy storage system 10. The communicator 21 receives information on the state of charge, voltage, and temperature from the energy storage system 10. The communicator 21 may receive information periodically or in real time from the energy storage system 10 under the control of the controller 25.

The storage 23 stores a program for controlling the operation of the calculation apparatus 20 and information generated during the execution of the program. The storage 23 stores an execution program that calculates an integrated safety for the state of the energy storage system 10 based on fuzzy logic for information collected from the energy storage system 10. The storage 23 may store the information collected from the energy storage system 10.

The controller 25 is a processor that performs the overall control operation of the calculation apparatus 20. That is, the controller 25 calculates the integrated safety for the state of the energy storage system 10 based on fuzzy logic for information collected from the energy storage system 10.

The controller 25 can calculate the integrated safety as follows. The controller 25 defines a voltage safety membership function and a temperature safety membership function to which fuzzy logic will be applied. The controller 25 collects information on the state of charge, voltage, and temperature from the energy storage system 10. The controller 25 calculates the integrated safety by applying a fuzzy rule to the voltage safety and temperature safety membership functions for the collected information. The controller 25 calculates a total integrated safety by summing up the calculated integrated safety. The controller 25 calculates an instantaneous integrated safety through defuzzification for the total integrated safety. Then, the controller 25 calculates the integrated safety for a specific period by calculating the average of the calculated instantaneous integrated safety by period.

Since the instantaneous integrated safety and the integrated safety for a specific period calculated by the controller 25 are safety indicators calculated based on indicators for not only voltage but also state of charge and temperature, it is possible to more accurately recognize and prevent dangerous situations such as fire and explosion of the energy storage system 10 in advance.

The controller 25 defines a membership function for each type of collected information to infer the integrated safety using the Mamdani method. That is, it defines a voltage safety membership function and a temperature safety membership function. For example, in the voltage safety membership function, the X-axis denotes the battery voltage according to charge or discharge, and the Y-axis denotes the degree of membership. In the temperature safety membership function, the X-axis denotes the battery temperature, and the Y-axis denotes the degree of membership.

The membership values of each indicator can be represented in a rule-based table through the membership function generated through fuzzification. In this embodiment, as shown in Table 1, the integrated safety result regarding how safe the current battery state is can be represented by referring to the truth table (fuzzy rule) of the voltage safety and the temperature safety for each indicator according to the battery charging state.

TABLE 1

| | temperature safety | | | | |
|---|---|---|---|---|---|
| | Catastrophic | Critical | Neutral | Marginal | Negligible |
| | (E) | (D) | (C) | (B) | (A) |
| voltage safety | (Very dangerous) | (Dangerous) | (Normal) | (Safe) | (Very safe) |
| Catastrophic | E | E | E | D | C |
| (E) | | | | | |
| (Very dangerous) | | | | | |
| Critical | E | D | D | C | B |
| (D) | | | | | |
| (Dangerous) | | | | | |
| Neutral | E | D | C | C | B |
| (C) | | | | | |
| (Normal) | | | | | |
| Marginal | D | C | C | B | B |
| (B) | | | | | |
| (Safe) | | | | | |
| Negligible | C | B | B | B | A |
| (A) | | | | | |
| (Very safe) | | | | | |

Table 1 shows the integrated safety that defines a fuzzy rule for voltage safety and temperature safety. Each safety is expressed in five stages (A, B, C, D, and E). For example, if the voltage safety is A and the temperature safety is C, the integrated safety is B.

The controller 25 can calculate the integrated safety using Equation 1 below. That is, when the voltage safety and temperature safety membership functions defined according to the state of charge, voltage, and temperature of the information collected in real time are X and Y, respectively, and when the integrated safety, which is the output value, is Z, the controller 25 calculates the integrated safety Z by clipping the value calculated using prod as the AND (logical product) operation evaluation method according to the fuzzy rule of Table 1.

$$μ X∩Y ( x ) = p r od [ μ X ( x ) , μ Y ( x ) ] = μ X ( x ) \times μ Y ( x ) = Z ( x ) \qquad EQUATION 1$$

Z: Integrated safety
X: Voltage safety membership function
x: Voltage
Y: Temperature safety membership function
y: Temperature
μ: Weight

The controller 25 can calculate the instantaneous integrated safety (c) through defuzzification by using the center of gravity method according to Equation 2 below. That is, the controller 25 calculates the total integrated safety by summing up all the integrated safety calculated using Equation 1. The controller 25 can calculate the instantaneous integrated safety (c) by using the center of gravity method through defuzzification of the total integrated safety.

$$c = \frac{{{\sum }_{x = a}}^{b} μ A ( x ) x}{{{\sum }_{x = a}}^{b} μ A ( x )} \qquad EQUATION 2$$

c: Instantaneous integrated safety
A: Membership function
x: Calculated integrated safety
μ: Weight

In addition, the controller 25 can calculate the integrated safety for a specific period by calculating the period-by-period average for the calculated instantaneous integrated safety (c).

As such, the calculation apparatus 20 according to this embodiment can calculate the integrated safety regarding how safe the battery is through the indicators of voltage safety and temperature safety to which weights are given according to the battery charge state.

### State Safety Calculation Method

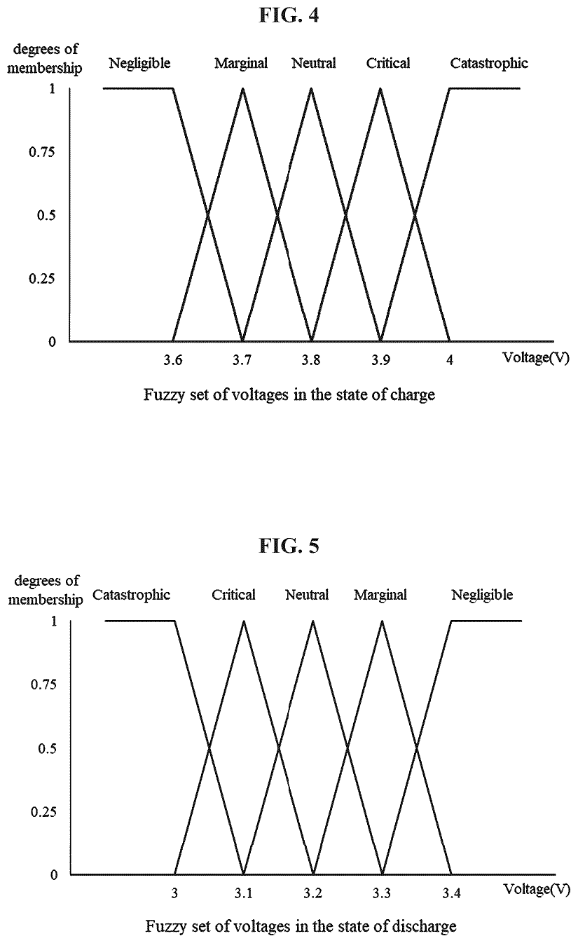

Now, a fuzzy logic based method for calculating the state safety of the energy storage system 10 using the calculation system 100 according to the embodiment is described with reference to FIGS. 1 to 3. Here, FIG. 3 is a flowchart showing a fuzzy logic based method for calculating a state safety of an energy storage system according to an embodiment of the present disclosure.

First, in step S10, the calculation apparatus 20 defines a voltage safety membership function and a temperature safety membership function in order to calculate the integrated safety based on fuzzy logic.

Next, in step S20, the calculation apparatus 20 collects information on the state of charge, voltage, and temperature of the battery from the energy storage system 10. The calculation apparatus 20 may collect information on the energy storage system 10 in real time.

Next, in step S30, the calculation apparatus 20 calculates the integrated safety by using a fuzzy rule and Equation 1 for the voltage safety and temperature safety membership functions.

Next, in step S40, the calculation apparatus 20 calculates the total integrated safety by summing up the calculated integrated safety.

Then, in step S50, the calculation apparatus 20 calculates the instantaneous integrated safety by using Equation 2 through defuzzification of the total integrated safety.

Additionally, in step S60, the calculation apparatus 20 calculates the integrated safety for a specific period by calculating the average of the instantaneous integrated safety for each period.

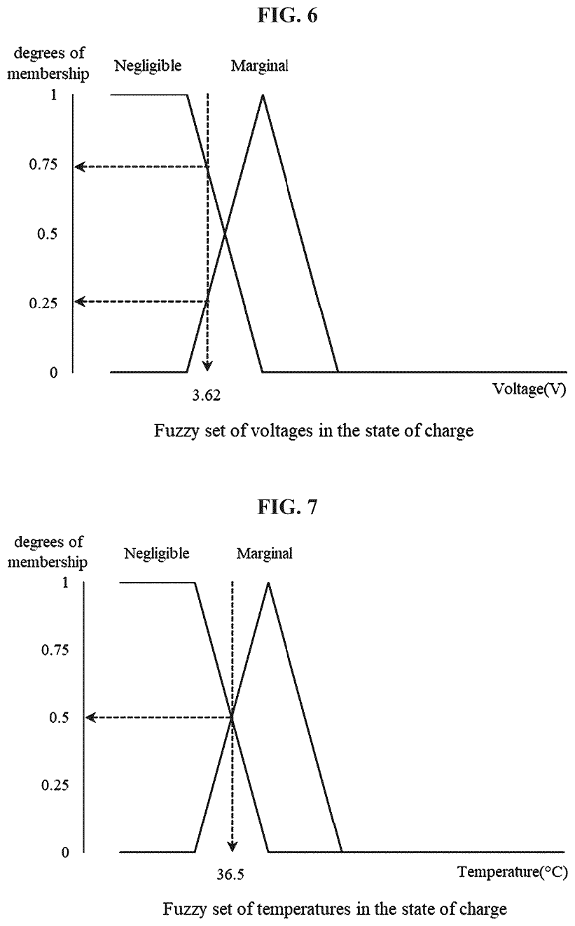

Hereinafter, the method for calculating the state safety according to the embodiment is described using examples shown in FIGS. 4 to 13. Here, FIGS. 4 to 13 are diagrams showing a process of calculating an instantaneous integrated safety according to the state safety calculation method in FIG. 3.

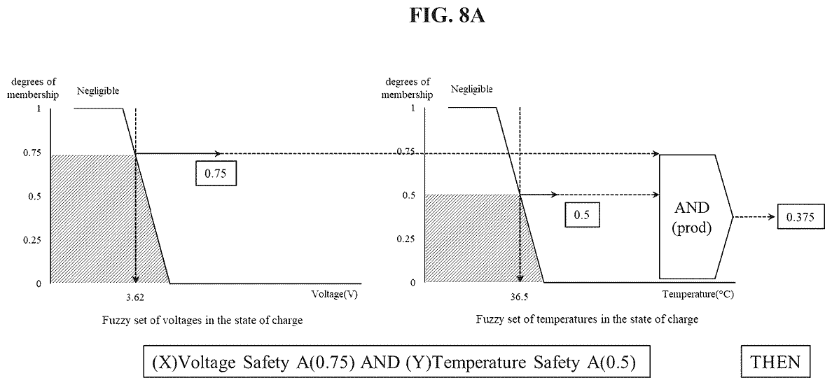

FIG. 4 is a graph showing a voltage safety membership function that defines a fuzzy set for the state of charge. FIG. 5 is a graph showing a voltage safety membership function that defines a fuzzy set for the state of discharge.

FIGS. 4 and 5 show the voltage safety membership function that defines a fuzzy set according to voltage values in the state of charge and the state of discharge, respectively. Here, the Y-axis denotes the degrees of membership, and the X-axis denotes the voltage of the battery.

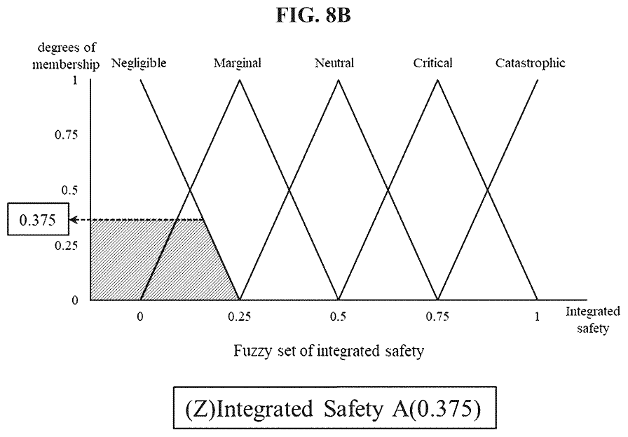

When the information collected in real time from the energy storage system 10 is as shown in Table 2, the integrated safety can be calculated as shown in FIGS. 6 to 11. Here, FIGS. 6 to 11 are graphs for setting an integrated safety calculated by applying a fuzzy rule to a membership function for the state of charge, voltage, and temperature,

TABLE 2

| | Charging | Voltage | Temperature |
|---|---|---|---|
| Time | status | (V) | (° C.) |
| 2022 Nov. 8 | charging | 3.62 | 36.5 |
| 14:37:59.000 + 0900 | | | |
| 2022 Nov. 8 | charging | 3.62 | 36.7 |
| 14:38:00.000 + 0900 | | | |
| 2022 Nov. 8 | charging | 3.63 | 36.9 |
| 14:38:01.000 + 0900 | | | |
| 2022 Nov. 8 | charging | 3.65 | 37.0 |
| 14:38:02.000 + 0900 | | | |
| . . . | . . . | . . . | . . . |

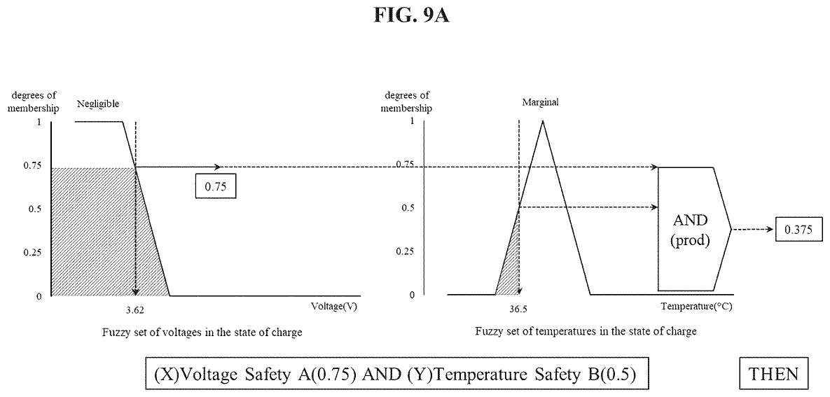

FIG. 6 shows the voltage safety membership function, and FIG. 7 shows the temperature safety membership function.

The voltage safety and temperature safety membership functions defined according to the state of charge, voltage, and temperature of the information collected in real time in Table 2 are X and Y, respectively, and the integrated safety, which is the output value, is Z.

In Table 2, the case where information is collected from the energy storage system 10 at 2022-11-08, 14:37:59, and the voltage and the temperature in the state of charge are 3.62V and 36.5° C., respectively, is explained as follows.

First, when the voltage is 3.62V, X corresponds to Negligible (A) 0.75% and Marginal (B) 0.25%. When the temperature is 36.5° C., Y corresponds to Negligible (A) 0.5% and Marginal (B) 0.5%.

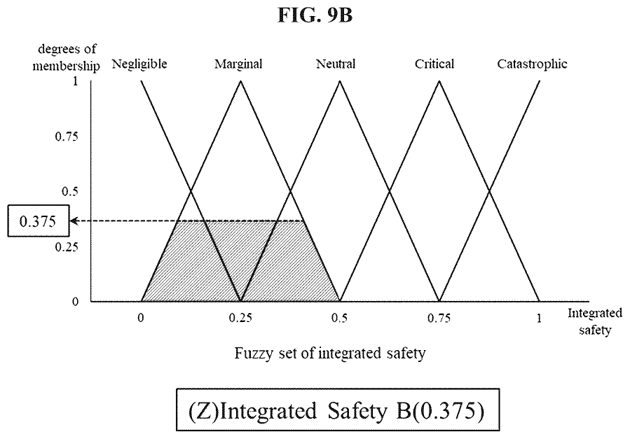

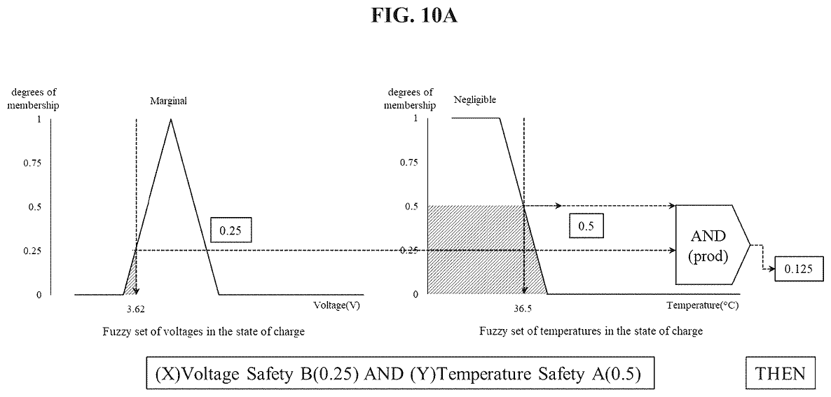

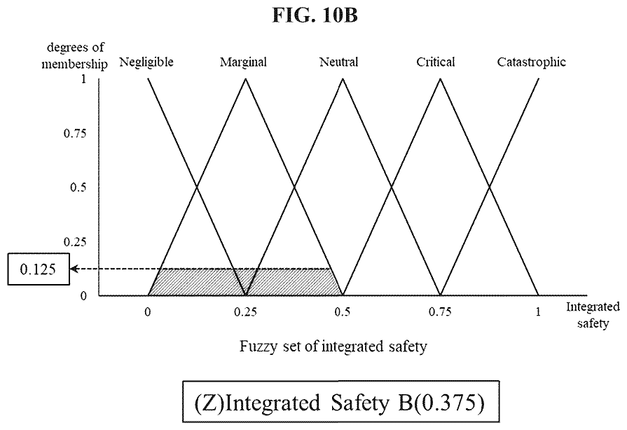

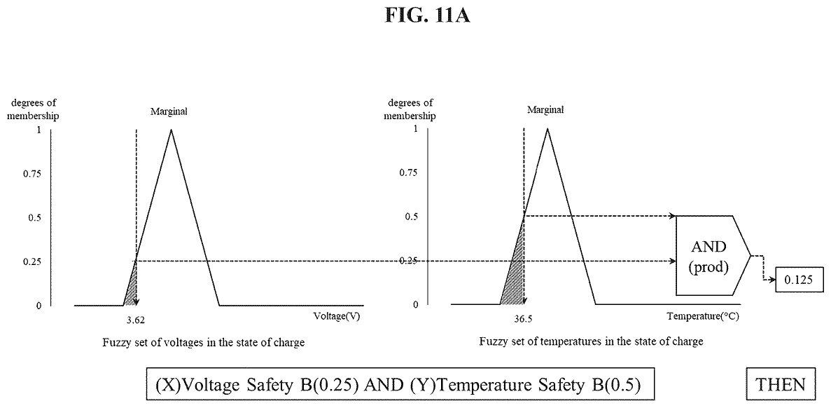

When clipping the value obtained by using prod as the AND operation evaluation method according to the fuzzy rule in Table 1, the integrated safety (Z) is calculated as Negligible (A) 0.375% (FIG. 8A and FIG. 8B), Marginal (B) 0.375% (FIG. 9A and FIG. 9B), Marginal (B) 0.125% (FIG. 10A and FIG. 10B), and Marginal (B) 0.125% (FIG. 11A and FIG. 11B).

That is, in the case of information on voltage and temperature in the state of charge collected at 2022-11-08, 14:37:59, there are two membership functions for each of the voltage safety and the temperature safety, and thus the calculation apparatus 20 calculates four pieces of integrated safety (Z).

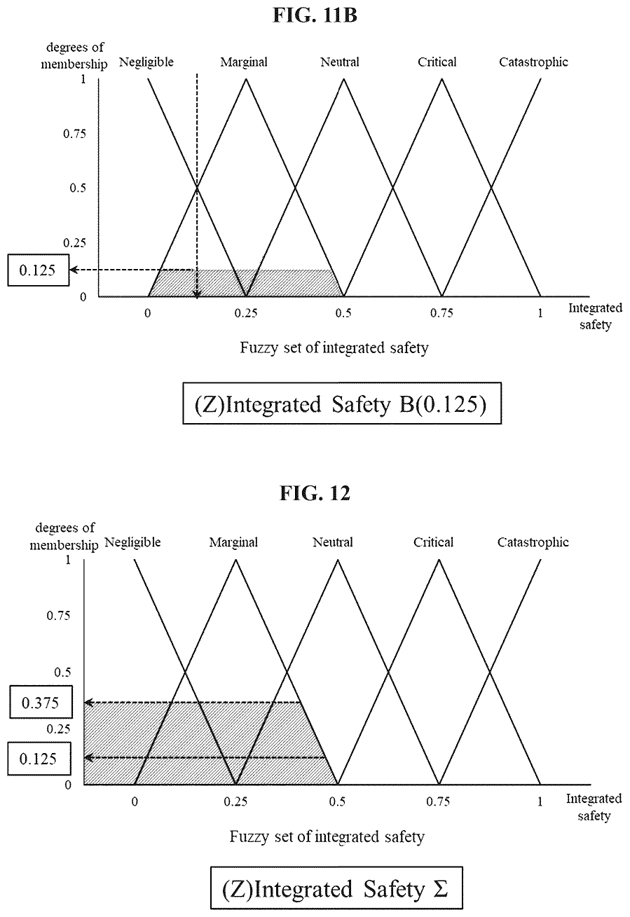

FIG. 12 is a graph showing a total integrated safety obtained by summing up the calculated integrated safety.

Referring to FIG. 12, the calculation apparatus 20 calculates the total integrated safety by summing up four pieces of integrated safety.

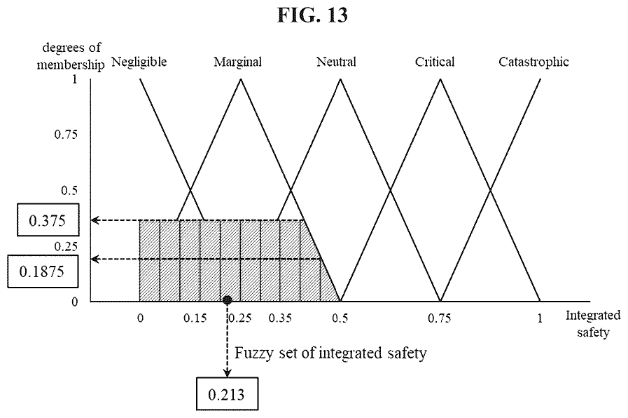

FIG. 13 is a graph showing an instantaneous integrated safety calculated through defuzzification of the total integrated safety.

Referring to FIG. 13, the calculation apparatus 20 calculates the instantaneous integrated safety calculated through defuzzification of the total integrated safety. That is, the calculation apparatus 20 calculates the instantaneous integrated safety by using the center of gravity method according to Equation 2 for defuzzification.

If the instantaneous integrated safety is calculated using the center of gravity method for the information collected at 2022-11-08, 14:37:59, an approximate value of 0.213 can be obtained. That is, if the four pieces of integrated safety (Z) calculated in FIGS. 8 to 11 are substituted into Equation 2, it can be expressed as Equation 3 below, and an instantaneous integrated safety with an approximate value of 0.213 can be calculated.

$$c ≅ \frac{0.375 \times ( 0 + 0.05 + 0.1 + 0.15 + 0.2 + 0.25 + 0.3 + 0.35 + 0.4 ) + 0.1875 \times ( 0.45 ) + 0 \times ( 0 \text{.5} )}{0.375 \times 9 + 0.1875 + 0} \qquad EQUATION 3$$

Also, in the same way as calculating the instantaneous integrated safety for the information collected at 2022-11-08, 14:37:59, the calculation apparatus 20 can calculate the instantaneous integrated safety for each collected time based on the information collected in Table 2.

Finally, the calculation apparatus 20 can calculate the integrated safety for a specific period by calculating the average value for each period for the calculated instantaneous integrated safety.

While the present disclosure has been particularly shown and described with reference to an exemplary embodiment thereof, it will be understood by those skilled in the art that various changes in form and details may be made therein without departing from the scope of the present disclosure as defined by the appended claims.

1. A fuzzy logic based method for calculating a state safety of an energy storage system, the method comprising:
by a state safety calculation apparatus, defining a voltage safety membership function and a temperature safety membership function;
by the state safety calculation apparatus, collecting information on charge state, voltage, and temperature from the energy storage system;
by the state safety calculation apparatus, calculating an integrated safety by applying a fuzzy rule to the voltage safety membership function and the temperature safety membership function for the collected information;
by the state safety calculation apparatus, calculating a total integrated safety by summing up the calculated integrated safety; and
by the state safety calculation apparatus, calculating an instantaneous integrated safety through defuzzification of the total integrated safety,
wherein the fuzzy rule represents the voltage safety and the temperature safety as shown in the Table below
TABLE

| | temperature safety | | | | |
|---|---|---|---|---|---|
| | Catastrophic | Critical | Neutral | Marginal | Negligible |
| | (E) | (D) | (C) | (B) | (A) |
| voltage safety | (Very dangerous) | (Dangerous) | (Normal) | (Safe) | (Very safe) |
| Catastrophic | E | E | E | D | C |
| (E) | | | | | |
| (Very dangerous) | | | | | |
| Critical | E | D | D | C | B |
| (D) | | | | | |
| (Dangerous) | | | | | |
| Neutral | E | D | C | C | B |
| (C) | | | | | |
| (Normal) | | | | | |
| Marginal | D | C | C | B | B |
| (B) | | | | | |
| (Safe) | | | | | |
| Negligible | C | B | B | B | A |
| (A) | | | | | |
| (Very safe) | | | | | |

2. The method of claim 1, further comprising:
after calculating the instantaneous integrated safety,
by the state safety calculation apparatus, calculating the integrated safety for a specific period by calculating an average of the instantaneous integrated safety for each period.

3. The method of claim 2, wherein the state safety calculation apparatus defines the voltage safety membership function and the temperature safety membership function to infer the integrated safety using Mamdani method.

4. (canceled)

5. The method of claim 3, wherein the state safety calculation apparatus calculates the integrated safety using Equation 1 below
$$μ X∩Y ( x , y ) = p r od [ μ X ( x ) , μ Y ( y ) ] = μ X ( x ) \times μ Y ( y ) = Z ( x , y ) \qquad EQUATION 1$$
Z: Integrated safety
X. Voltage safety membership function
x: Voltage
Y: Temperature safety membership function
y: Temperature
μ: Weight.

6. The method of claim 5, wherein the state safety calculation apparatus calculates the instantaneous integrated safety (c) through defuzzification by using a center of gravity method according to Equation 2 below
$$c = \frac{{{\sum }_{x = a}}^{b} μ A ( x ) x}{{{\sum }_{x = a}}^{b} μ A ( x )} \qquad EQUATION 2$$
c: Instantaneous integrated safety
A: Membership function
x: Calculated integrated safety
μ: Weight
a: Starting value of input range where membership function (A is defined
b: Ending value of input range where membership function (A) is defined.

7. A fuzzy logic based apparatus for calculating a state safety of an energy storage system, the apparatus comprising:
a communicating interface configured to perform communication with the energy storage system; and
a controller in data communication with the communication interface and configured to:
define a voltage safety membership function and a temperature safety membership function,
collect information on charge state, voltage, and temperature from the energy storage system through the communicator,
calculate an integrated safety by applying a fuzzy rule to the voltage safety membership function and the temperature safety membership function for the collected information,
calculate a total integrated safety by summing up the calculated integrated safety, and
calculate an instantaneous integrated safety through defuzzification of the total integrated safety,
wherein the fuzzy rule represents the voltage safety and the temperature safety as shown in the Table below
TABLE

| | temperature safety | | | | |
|---|---|---|---|---|---|
| | Catastrophic | Critical | Neutral | Marginal | Negligible |
| | (E) | (D) | (C) | (B) | (A) |
| voltage safety | (Very dangerous) | (Dangerous) | (Normal) | (Safe) | (Very safe) |
| Catastrophic | E | E | E | D | C |
| (E) | | | | | |
| (Very dangerous) | | | | | |
| Critical | E | D | D | C | B |
| (D) | | | | | |
| (Dangerous) | | | | | |
| Neutral | E | D | C | C | B |
| (C) | | | | | |
| (Normal) | | | | | |
| Marginal | D | C | C | B | B |
| (B) | | | | | |
| (Safe) | | | | | |
| Negligible | C | B | B | B | A |
| (A) | | | | | |
| (Very safe) | | | | | |

8. A fuzzy logic based system for calculating a state safety of an energy storage system, the system comprising:
the energy storage system; and
a state safety calculation apparatus in data communication with the energy storage system and configured to:
define a voltage safety membership function and a temperature safety membership function,
collect information on charge state, voltage, and temperature from the energy storage system,
calculate an integrated safety by applying a fuzzy rule to the voltage safety membership function and the temperature safety membership function for the collected information,
calculate a total integrated safety by summing up the calculated integrated safety, and
calculate an instantaneous integrated safety through defuzzification of the total integrated safety,
wherein the fuzzy rule represents the voltage safety and the temperature safety as shown in the Table below
TABLE

| | temperature safety | | | | |
|---|---|---|---|---|---|
| | Catastrophic | Critical | Neutral | Marginal | Negligible |
| | (E) | (D) | (C) | (B) | (A) |
| voltage safety | (Very dangerous) | (Dangerous) | (Normal) | (Safe) | (Very safe) |
| Catastrophic | E | E | E | D | C |
| (E) | | | | | |
| (Very dangerous) | | | | | |
| Critical | E | D | D | C | B |
| (D) | | | | | |
| (Dangerous) | | | | | |
| Neutral | E | D | C | C | B |
| (C) | | | | | |
| (Normal) | | | | | |
| Marginal | D | C | C | B | B |
| (B) | | | | | |
| (Safe) | | | | | |
| Negligible | C | B | B | B | A |
| (A) | | | | | |
| (Very safe) | | | | | |
